(19) United States
(12) Patent Application Publication
(10) Pub. No.: US 2019/0273028 A1
(43) Pub. Date: Sep. 5, 2019

(54) DEVICE STRUCTURES FORMED WITH A SILICON-ON-INSULATOR SUBSTRATE THAT INCLUDES A TRAP-RICH LAYER

(71) Applicant: GLOBALFOUNDRIES Inc., Grand Cayman (KY)

(72) Inventors: Vibhor Jain, Essex Junction, VT (US); Anthony K. Stamper, Williston, VT (US)

(21) Appl. No.: 15/910,603

(22) Filed: Mar. 2, 2018

(51) Int. Cl. H01L 21/84; H01L 27/12; H01L 21/762

(52) U.S. Cl. CPC H01L 21/84; H01L 21/8252; H01L 21/76264; H01L 27/1207

(57) ABSTRACT

Structures and methods associated with a silicon-on-insulator substrate are needed. A silicon-on-insulator substrate is provided that includes a device layer of single-crystal semiconductor material, a buried oxide layer, a handle wafer of single-crystal semiconductor material, and a non-single-crystal semiconductor layer between the handle wafer and the buried oxide layer. A trench is formed that extends through the device layer, the buried oxide layer, and the non-single-crystal semiconductor layer to the handle wafer. A semiconductor layer is epitaxially grown from the handle wafer to at least partially fill the trench, and a device structure is formed using at least a portion of the semiconductor layer.

### BACKGROUND

The invention relates generally to semiconductor devices and integrated circuit fabrication and, in particular, to structures and methods associated with a silicon-on-insulator substrate.

Devices fabricated using silicon-on-insulator (SOI) technologies may exhibit certain performance improvements in comparison with comparable devices built directly in a bulk silicon substrate. Generally, an SOI wafer includes a thin device layer of semiconductor material, a handle substrate, and a thin buried oxide (BOX) layer, physically separating and electrically isolating the device layer from the handle substrate.

The device structures, such as the device structures found in power amplifiers, of integrated circuits may be fabricated using the semiconductor material of the device layer. When powered during operation, the device structures generate heat that must be dissipated to avoid failures. However, for an SOI wafer, the dissipation of heat from the device layer to the handle wafer is hindered by the intervention of the BOX layer, which is composed of a dielectric material, such as silicon dioxide, characterized by a low thermal conductivity.

Improved structures and methods associated with a silicon-on-insulator substrate are needed.

### SUMMARY

In an embodiment of the invention, a structure includes a silicon-on-insulator substrate having a handle wafer, a buried oxide layer, a device layer, and a non-single-crystal semiconductor layer between the buried oxide layer and the handle wafer. The device layer and handle wafer are composed of single-crystal semiconductor material. The structure further includes a single-crystal semiconductor layer extending from the handle wafer through the non-single-crystal semiconductor layer toward the buried oxide layer, as well as a device structure at least partially in the single-crystal semiconductor layer. The non-single-crystal semiconductor layer is arranged to surround the single-crystal semiconductor layer.

In an embodiment of the invention, a method includes providing a silicon-on-insulator substrate including a device layer composed of single crystal semiconductor material, a buried oxide layer, a handle wafer composed of single crystal semiconductor material, and a non-single-crystal semiconductor layer between the single-crystal handle wafer and the buried oxide layer. The method further includes forming a trench extending through the device layer, the buried oxide layer, and the non-single-crystal semiconductor layer to the handle wafer. A semiconductor layer is epitaxially grown from the handle wafer to at least partially fill the trench, and a device structure is formed using at least a portion of the semiconductor layer.

### BRIEF DESCRIPTION OF THE DRAWINGS

The accompanying drawings, which are incorporated in and constitute a part of this specification and which are not drawn to scale, illustrate various embodiments of the invention and, together with a general description of the invention given above and the detailed description of the embodiments given below, serve to explain the embodiments of the invention.

FIGS. 1-5 are cross-sectional views of a structure at successive fabrication stages of a processing method for fabricating a device structure in accordance with an embodiment of the invention.

FIG. 6 is a cross-sectional view of a structure fabricated by a processing method in accordance with an alternative embodiment of the invention

FIGS. 7-8 are cross-sectional views of a structure at successive fabrication stages of a processing method for fabricating a structure in accordance with an alternative embodiment of the invention.

### DETAILED DESCRIPTION

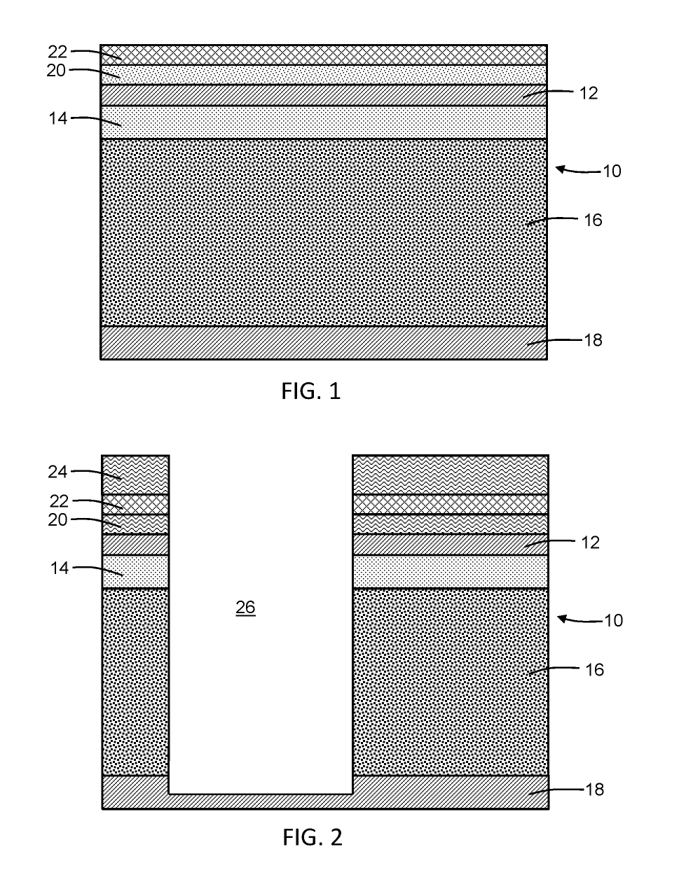

With reference to FIG. 1 and in accordance with an embodiment of the invention, a semiconductor substrate 10 is provided that may be a semiconductor-on-insulator (SOI) substrate including a device layer 12, a buried oxide (BOX) layer 14, trap-rich layer 16, and a handle wafer 18. The device layer 12 is separated from the trap-rich layer 16 and the handle wafer 18 by the intervening BOX layer 14 and may be considerably thinner than either the trap-rich layer 16 or the handle wafer 18. The device layer 12 is arranged over the BOX layer 14 and is electrically insulated from the trap-rich layer 16 and the handle wafer 18 by the intervening BOX layer 14. The BOX layer 14 may be composed of an electrical insulator, such as silicon dioxide (e.g., SiO₂). The device layer 12 and the handle wafer 18 may be composed of a single-crystal semiconductor material, such as single-crystal silicon (Si).

The trap-rich layer 16 may be composed of a trap-rich semiconductor material, such as a polycrystalline semiconductor material or another type of non-single-crystal semiconductor material. In an embodiment, the trap-rich layer 16 may be composed of polycrystalline silicon (i.e., polysilicon) deposited by chemical vapor deposition (CVD) under deposition conditions (e.g., temperature and pressure) selected to impart a high density of electrically-active carrier traps. In an embodiment, the deposition conditions may be selected to introduce carrier traps at a density that imparts the trap-rich layer 16 with an elevated electrical resistivity that is on the order of 0.1 kΩ-cm to 10 kΩ-cm. In another embodiment, the trap-rich layer 16 may include damaged semiconductor material that has an electrical resistivity that is on the order of 0.1 kΩ-cm to 10 kΩ-cm. The damaged semiconductor material may include a density of crystalline defects in the semiconductor material that provide the carrier traps, or may be composed of amorphous semiconductor material. In an embodiment, the trap-rich layer 16 may be introduced by implanting the handle wafer 18 across a given thickness with an energetic ion species, such as argon ions. In an embodiment, the trap-rich layer 16 may have a nominal thickness of 0.5 microns (μm) to 2 microns.

Pad layers 20, 22 are arranged on a top surface 11 of the device layer 12. The materials forming the pad layers 20, 22 may be chosen to etch selectively to the semiconductor material constituting the device layer 12 and to be readily removed at a subsequent fabrication stage. The pad layers 20, 22 operate as protection layers for the top surface 11 of the device layer 12 during, for example, etching processes. The pad layer 20 may be composed of a dielectric material, such as silicon dioxide (SiO₂) grown by oxidizing the top surface 11 of device layer 12 or deposited by chemical vapor deposition (CVD). The pad layer 22 may be composed of a dielectric material, such as silicon nitride (Si₃N₄) deposited by chemical vapor deposition (CVD).

With reference to FIG. 2 in which like reference numerals refer to like features in FIG. 1 and at a subsequent fabrication stage of the processing method, a patterned etch mask 24 is formed on a top surface of the pad layer 22. The etch mask 24 may include a photoresist that is applied by a spin coating process, pre-baked, exposed to a radiation projected through a photomask, baked after exposure, and developed with a chemical developer to form an opening at an intended location for an opening extending into the semiconductor substrate 10.

An etching process is used to define a trench 26 at the location of the opening in the etch mask 24. The trench 26 extends completely through the respective thicknesses of the pad layers 20, 22, the device layer 12, the BOX layer 14, and the trap-rich layer 16 and penetrates to a shallow depth into the handle wafer 18. The etching process, which may involve reactive ion etching (RIE), may be conducted in a single etching step or multiple etching steps, and may rely on one or more etch chemistries. The etch mask 24 may be removed after the trench 26 is formed by the etching process.

In the representative embodiment, the trench 26 penetrates to a shallow depth into the handle wafer 18. In an alternative embodiment, the trench 26 may terminate at the interface between the trap-rich layer 16 and the handle wafer 18.

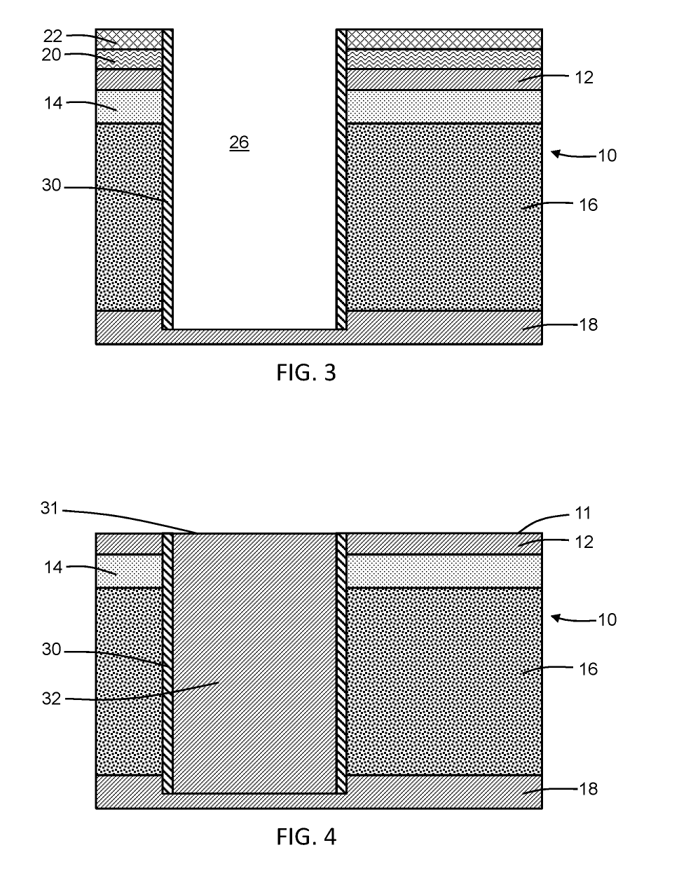

With reference to FIG. 3 in which like reference numerals refer to like features in FIG. 2 and at a subsequent fabrication stage of the processing method, non-conductive spacers 30 are formed on the sidewalls of the trench 26 and may extend vertically relative to the surface of the handle wafer 18 exposed at the bottom of the trench 26. The spacers 30 may be formed by depositing a conformal layer comprised of an electrical insulator, such as silicon nitride (Si₃N₄) deposited by chemical vapor deposition, and shaping the conformal layer with a directional etching process, such as reactive ion etching (RIE). In an embodiment, after the spacers 30 are formed, the surface of the handle wafer 18 exposed at the bottom of the trench 26 may be oxidized using a high-temperature oxidation and the product oxide removed with an oxide etch to remove defects at the exposed surface of the handle wafer 18.

With reference to FIG. 4 in which like reference numerals refer to like features in FIG. 3 and at a subsequent fabrication stage of the processing method, a semiconductor layer 32 may be formed inside the trench 26 using an epitaxial growth process after the non-conductive spacers 30 are formed. Epitaxial growth is a process by which the single-crystal semiconductor material of the semiconductor layer 32 is grown on the single-crystal semiconductor material of the handle wafer 18 and in which the crystal orientation and crystal structure of the single-crystal material of the handle wafer 18 is reproduced in the semiconductor material of the semiconductor layer 32. During epitaxial growth, the semiconductor material of the semiconductor layer 32 will acquire the crystal orientation and crystal structure of the single-crystal semiconductor material of the handle wafer 18, which serves as a template for growth. In an embodiment, the epitaxial growth process may be a selective epitaxial growth (SEG) process. The non-conductive spacers 30 block epitaxial growth of the semiconductor material of the semiconductor layer 32 from the surfaces of the device layer 12 and trap-rich layer 16 surrounding the trench 26 at its sidewalls.

The single-crystal semiconductor material of the semiconductor layer 32 is surrounded by the non-single-crystal semiconductor material of the trap-rich layer 16, and the semiconductor layer 32 extends from the handle wafer 18 in a vertical direction toward the BOX layer 14. In an embodiment, the trench 26 may be overfilled with the epitaxial semiconductor material such that the top surface 31 of the semiconductor layer 32 projects out of the trench 26. The top surface 31 of the semiconductor layer 32 may be planarized using chemical-mechanical polishing (CMP) to be coplanar with the top surface 11 of the device layer 12. The semiconductor layer 32 may extend through the BOX layer 14 and the device layer 12 to the top surface 11 of the device layer 12, as shown in the representative embodiment, or the top surface 31 of the semiconductor layer 32 may be recessed relative to the top surface 11 of the device layer 12 as subsequently described in connection with FIG. 6.

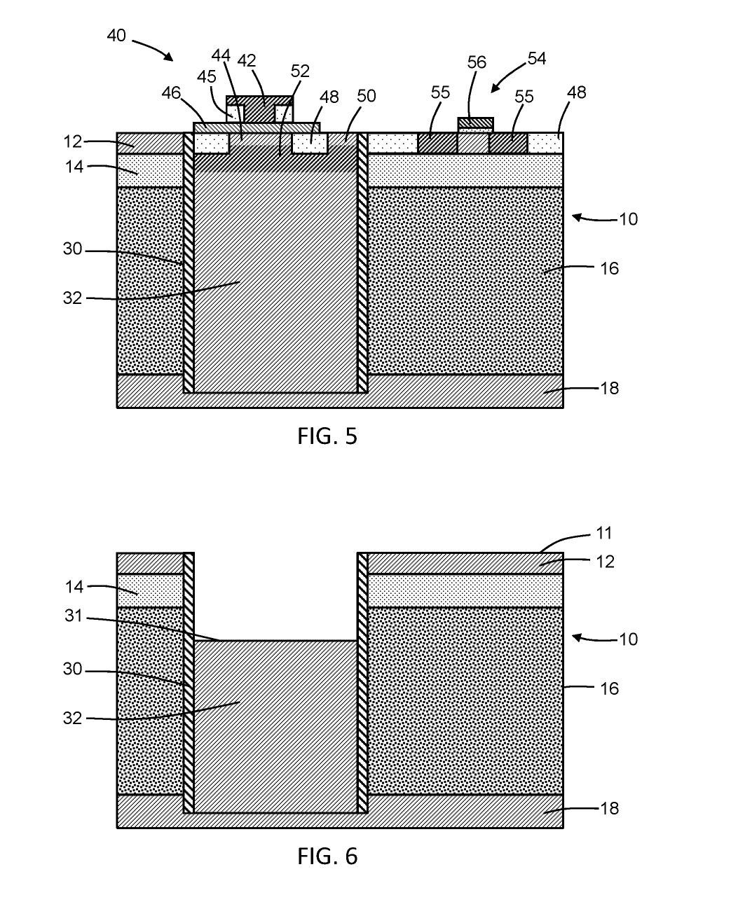

With reference to FIG. 5 in which like reference numerals refer to like features in FIG. 4 and at a subsequent fabrication stage of the processing method, a device structure 40 is formed using the semiconductor layer 32 by a front-end-of-line (FEOL) fabrication process. Shallow trench isolation (STI) layer 48 is formed by, for example, patterning, etching trenches, filling the trenches with a dielectric such as oxide, and using CMP to remove the excess oxide from the surface of the device layer 12. In embodiments, the depth of the STI layer 48 may be extended by etching through the device layer 12 to touch or extend into the BOX layer 14. The device structure 40 may be a bipolar junction transistor that includes an emitter 42, a collector 44, a base layer 46 that is arranged vertically between the emitter 42 and the collector 44, and an insulator layer 45 between the wings of the emitter 42 and the base layer 46, as well as dielectric spacers (not shown). The device structure 40 may be characterized as a heterojunction bipolar transistor (HBT) if two or all three of the emitter 42, the collector 44, and the base layer 46 are comprised of different semiconductor materials. The device structure 40 may be configured as a component of a power amplifier. The STI layer 48 inside the semiconductor layer 32 may separate the base layer 46 from a collector contact 50, and a sub-collector 52 arranged beneath the collector 44 may extend laterally in the semiconductor layer 32 beneath the STI layer 48 to the collector contact 50. The base layer 46 may be composed of a semiconductor material, such as silicon-germanium (SiGe) in an alloy with a content of silicon (Si) ranging from 95 atomic percent to 50 atomic percent and a content of germanium (Ge) ranging from 5 atomic percent to 50 atomic percent. The germanium content of the base layer 46 may be graded and/or stepped across its thickness. The base layer 46 may contain a p-type dopant selected from Group III of the Periodic Table (e.g., boron) that provides p-type conductivity. The base layer 46 may be formed on a top surface 31 of the semiconductor layer 32 using an epitaxial growth process. The emitter 42, collector 44, collector contact 50, and sub-collector 52 may contain an n-type dopant selected from Group V of the Periodic Table (e.g., phosphorus (P), arsenic (As), and/or antimony (Sb)) that provides n-type conductivity.

In alternative embodiments, the device structure 40 may be a high-voltage metal-oxide-semiconductor (HVMOS) field-effect transistor, a laterally-diffused metal-oxide-semiconductor (LDMOS) field-effect transistor, an extended-drain metal-oxide-semiconductor (EDMOS) field-effect transistor, etc. Another device structure 54 may be also formed using the device layer 12. In the representative embodiment, the device structure 54 may be either a p-type field-effect transistor (PFET) or an n-type field-effect transistor (NFET) including source/drain regions 55, the STI layer 48, a gate 56, and dielectric spacers (not shown). In alternative embodiments, the device structure 54 may be a bipolar junction transistor or heterojunction bipolar transistor of a low-noise amplifier, a switch comprised of a multi-finger p-type or n-type field-effect transistor, etc.

Middle-of-line (MOL) and back-end-of-line (BEOL) processing follows, which includes silicide formation, formation of contacts and wiring for a local interconnect structure to the device structures 40, 54, and formation of dielectric layers, via plugs, and wiring for an interconnect structure coupled by the local interconnect structure with the device structures 40, 54. Other active and passive circuit elements, such as diodes, resistors, capacitors, varactors, and inductors, may be integrated into the interconnect structure and available for use in the integrated circuit.

With reference to FIG. 6 in which like reference numerals refer to like features in FIG. 4 and in accordance with an alternative embodiment, the top surface 31 of the semiconductor layer 32 may be recessed relative to the top surface 11 of the device layer 12 before the device structure 40 is fabricated. The recessing of the top surface 31 of the semiconductor layer 32 places the device structure 40 closer to the handle wafer 18, which may provide enhanced heat dissipation from the device structure 40 to the heat sink supplied by the handle wafer 18. Alternatively, recessing the semiconductor layer 32 may allow for the device structure 40 to be coplanar or nearly coplanar with the device structure 54.

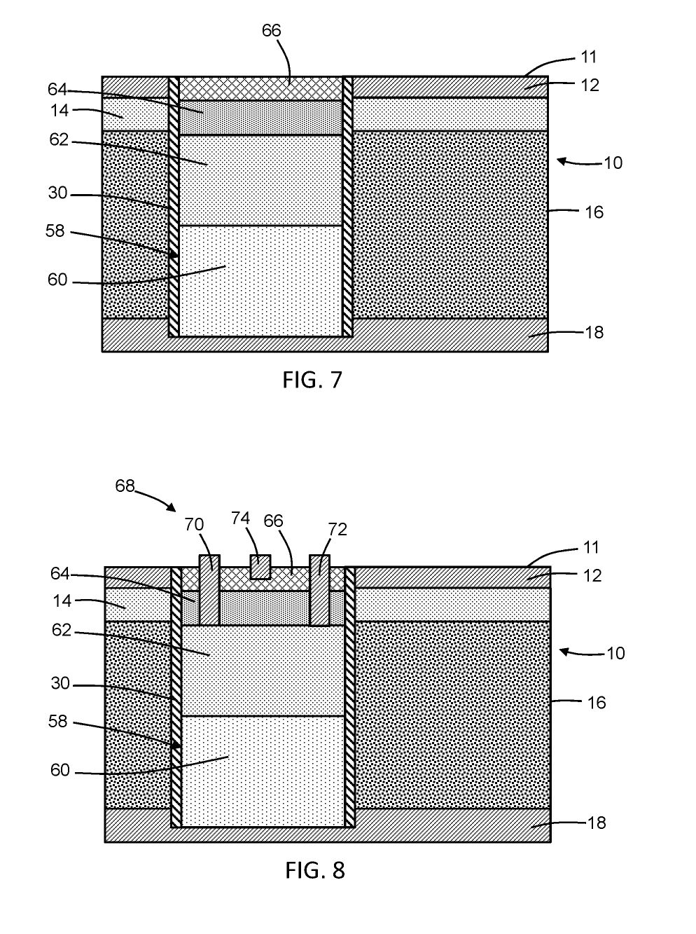

With reference to FIG. 7 in which like reference numerals refer to like features in FIG. 3 and in accordance with an alternative embodiment, a composite semiconductor layer 58 may be formed in the trench 26, after the non-conductive spacers 30 are formed, that includes epitaxially-grown layers 60, 62, 64 that are composed of III-V binary and ternary semiconductor materials, such as gallium nitride (GaN) and aluminum gallium nitride (AlGaN). The handle wafer 18 may be composed of a single-crystal semiconductor material with a crystal structure that promotes the epitaxial growth of the semiconductor layer 58, such as <111> single-crystal silicon. The device layer 12 may be composed of <100> or <110> silicon, which may result in improved mobility or other electrical characteristics of the device structure 54. For example, the device structure 54 could be a PFET formed on a device layer 12 composed of <110> single-crystal silicon or a NFET formed on a device layer 12 composed of <100> silicon. The layer 62 may be a channel layer and the layer 60 may be a buffer layer that is present to limit the propagation of defects during epitaxial growth into the layer 62. The layer 64 may be a barrier layer and, in an embodiment, may be composed of a ternary III-V semiconductor material (e.g., AlGaN) that differs in composition from a binary III-V semiconductor material (e.g., GaN) comprising the layer 62. A passivation layer 66 is formed over the composite semiconductor layer 58.

With reference to FIG. 8 in which like reference numerals refer to like features in FIG. 7 and at a subsequent fabrication stage of the processing method, a device structure 68 may be formed using the composite semiconductor layer 58. In an embodiment, the device structure 68 may be a High Electron Mobility Transistor (HEMT) that includes a source 70 and a drain 72 arranged in part in the layer 62 of the composite semiconductor layer 58, and a gate 74 arranged in the passivation layer 66 above the layer 62 of the composite semiconductor layer 58.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a dimension within the horizontal plane. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a silicon-on-insulator substrate having a handle wafer, a buried oxide layer, a device layer, and a non-single-crystal semiconductor layer between the buried oxide layer and the handle wafer, the device layer and the handle wafer composed of single-crystal semiconductor material, and the device layer providing a top surface of the silicon-on-insulator substrate;
a single-crystal semiconductor layer extending from the handle wafer through the device layer, the buried oxide layer, and the non-single-crystal semiconductor layer to the handle wafer, the single-crystal semiconductor layer having a top surface that is recessed relative to the top surface of the device layer; and
a first device structure at least partially in the single-crystal semiconductor layer,
wherein the non-single-crystal semiconductor layer surrounds the single-crystal semiconductor layer.

2. The structure of claim 1 wherein the non-single-crystal semiconductor layer is trap-rich semiconductor material, and has an electrical resistivity ranging from 0.1 kΩ-cm to 10 kΩ-cm.

3. The structure of claim 1 wherein the non-single-crystal semiconductor layer is damaged semiconductor material, and has an electrical resistivity ranging from 0.1 kΩ-cm to 10 kΩ-cm.

4. The structure of claim 1 wherein the non-single-crystal semiconductor layer is polycrystalline semiconductor material, and has an electrical resistivity ranging from 0.1 kΩ-cm to 10 kΩ-cm.

5. The structure of claim 1 further comprising:
a second device structure at least partially in the device layer.

6-7. (canceled)

8. The structure of claim 1 wherein the first device structure is a heterojunction bipolar transistor of a power amplifier.

9-10. (canceled)

11. The structure of claim 1 further comprising:
one or more spacers arranged between the single-crystal semiconductor layer and the non-single-crystal semiconductor layer that surrounds the single-crystal semiconductor layer.

12. A method comprising:
providing a silicon-on-insulator substrate including a device layer, a buried oxide layer, a handle wafer, and a non-single-crystal semiconductor layer between the handle wafer and the buried oxide layer, the device layer and the handle wafer composed of single-crystal semiconductor material;
forming a trench extending through the device layer, the buried oxide layer, and the non-single-crystal semiconductor layer to expose a surface of the handle wafer;
epitaxially growing a single-crystal semiconductor layer from the surface of the handle wafer at a bottom of the trench to at least partially fill the trench;
recessing a top surface of the single-crystal semiconductor layer relative to a top surface of the device layer; and
after recessing the top surface of the single-crystal semiconductor layer, forming a first device structure using at least a portion of the single-crystal semiconductor layer.

13. The method of claim 12 wherein the non-single-crystal semiconductor layer is trap-rich semiconductor material, damaged semiconductor material, or polycrystalline semiconductor material, and has an electrical resistivity ranging from 0.1 kΩ-cm to 10 kΩ-cm.

14. The method of claim 12 further comprising:
forming a second device structure at least partially in the device layer.

15-16. (canceled)

17. The method of claim 12 wherein the first device structure is a heterojunction bipolar transistor of a power amplifier.

18-19. (canceled)

20. The method of claim 12 further comprising:
after forming the trench and before epitaxially growing the non-single-crystal semiconductor layer, forming one or more spacers on the non-single-crystal semiconductor layer surrounding the trench.

21. The structure of claim 1 wherein the single-crystal semiconductor layer is arranged in part in the handle wafer.

22. The method of claim 12 wherein the bottom of the trench penetrates to a depth into the handle wafer.

23. The method of claim 12 further comprising:
oxidizing the surface of the handle wafer to form oxide; and
removing the oxide from the surface before epitaxially growing the single-crystal semiconductor layer from the surface of the handle wafer.
